(19) United States
(12) Patent Application Publication
(10) Pub. No.: US 2020/0162021 A1
(43) Pub. Date: May 21, 2020

(54) SOLAR PANEL WITH A COOLING DEVICE

(71) Applicant: Wei-Keng LIN, Hsinchu City (TW)

(72) Inventors: Wei-Keng LIN, Hsinchu City (TW); Shan-Chun MOU, Hsinchu City (TW)

(21) Appl. No.: 16/237,482

(22) Filed: Dec. 31, 2018

(30) Foreign Application Priority Data
Nov. 16, 2018 (TW) 107140687

(51) Int. Cl. H02S 40/42; H01L 31/052; F24S 80/30; F28D 15/02

(52) U.S. Cl. CPC H02S 40/425; F28D 15/0266; F24S 80/30; H01L 31/0521

(57) ABSTRACT

The invention provides a solar panel with a cooling device, comprising a solar panel with a substrate, a plurality of solar cells arranged on the substrate; a regenerative tank is stored with a Phase Change Material (PCM) inside; a pulsed heat pipe having a plurality of first bending section on one end of the pulsed heat pipe, and an extended section on the corresponding other end of the pulsed heat pipe to surround a plurality of second bending section; and a part of the extended section of the pulsed heat pipe is connected to the substrate of the solar panel, while the first bending section on the relative end of the extended section is extended into the regenerative tank and contacted with the phase change material. When the reduction of the temperature of the solar panel be achieved so that the efficiency of converting solar energy to electrical energy can be upgraded.

### FIELD OF THE INVENTION

This invention uses a solar panel with a cooling device, especially for the one uses a pulse heat pipe (PHP) to reduce the temperature of the solar panel in order to upgrade the efficiency of converting solar energy to electrical energy.

### BACKGROUND OF THE INVENTION

For the present invention, the solar panels can be used to convert solar energy to electrical energy. Therefore, solar panels have become an important tool for green energy source. However, solar panels are often overheated when they are in operation as they have absorbed solar energy for a long time. Also, the cells in the solar panels cannot be operated normally at high temperatures. It affects the efficiency of converting solar energy to electrical energy.

Therefore, current solar panels are to provide cooling methods for their solar cells. In the prior invention, besides cooling the cell through a fan, there is also a heat conduction component such as a heat pipe that has been applied. However, the conventional fan cooling method is very inefficient and an external power source is required to operate the fan. Although the efficiency can be improved through the heat pipe, its diameter is so large and it cannot be arranged easily. Also, after absorbing the heat, it is usually necessary to use a tool such as a fin-like or a fan-like to cool down the pipe. Using fin-like tool is actually insufficient to cool down the pipe. Also, if a fan is installed, there is still a problem that an extra external power supply is required.

According to what is mentioned above, the inventor has made an effort to improve and solve the problems mentioned above and has devoted himself to research. He proposed an improved design and it can effectively improve the defects mentioned above.

### SUMMARY OF THE INVENTION

The main object of the present invention is to provide a solar panel with a cooling device. This solar panel comprises a pulsed heat pipe. One end of the PHP is connected with the phase change material so that the efficiency of absorbing the heat can be enhanced as this phase change material has the characteristic of absorbing the heat. Once the efficiency of absorbing heat is enhanced, the temperature of the solar panel can be reduced and the efficiency of converting to the electrical energy for the whole cell of the solar panel can be upgraded.

In order to achieve the object mentioned above, the present invention provides a solar panel with a cooling device, comprising: a solar panel, a regenerative tank and a pulse heat pipe, wherein the solar panel comprises a substrate, a plurality of solar cells arranged on the substrate and a phase change material is arranged in the regenerative tank. The PHP is bent into a plurality of heat transfer section arranged at intervals. One end of the PHP forms a heat transfer segment arranged at complex intervals and the corresponding other end, which has an extended section to surround the heat transfer segment arranged at complex intervals. A part of the PHP is connected to the substrate with an extended section, while a part of the complex spaced heat transfer section on the relative end of the extended section is extended into the regenerative tank and contacted with the phase change material.

In an embodiment, the cooling device can be further arranged in a water tank and each heat transfer segment of the cooling device is in contact with water and let the water tank be connected with the solar panel as well. By doing so, the efficiency of converting to the electrical energy for the whole cell of the solar panel can be upgraded.

In an embodiment, when the pulse heat pipe of the cooling device is arranged at an angle. With this angle, the working liquid in the pulse heat pipe can flow so that the heat can be transferred to the regenerative tank.

In an embodiment of the present invention, after the pulse heat pipe is connected to the substrate of the solar panel by plural intervals of heat transfer sections (or evaporation sections) surrounded by the extended sections, when the temperature of the substrate of the solar panel rises, the heat can be transmitted to the condensing section of the phase change material comprises in the regenerated tank by plural intervals of the heat transfer sections of the pulse heat pipe and the heat source is absorbed by the phase change material to achieve the effect of cooling the solar panel so that the efficiency of converting to the electrical energy for the whole cell of the solar panel can be upgraded.

### BRIEF DESCRIPTION OF THE DRAWINGS

FIG. 1 is a schematic diagram of the pulsed heat pipe of the present invention on the XY coordinate plane.

FIG. 2 is a perspective view of the pulsed heat pipe module of the present invention.

FIG. 3 is a perspective view of a solar panel with a cooling device.

FIG. 4 is a top perspective view of the solar panel with a cooling device.

FIG. 5 is a schematic diagram of test results of a cooling device with the evaporation portion of the present invention.

FIG. 6 is one embodiment of a cross-sectional view of a solar panel with a cooling device according to the present invention on the Z-Y coordinate plane.

FIG. 7 is another embodiment of a cross-sectional view of a solar panel with a cooling device according to the present invention on the Z-Y coordinate plane.

FIG. 8a is a schematic diagram showing temperature test results of a solar panel with a cooling device and a general solar panel according to the present invention.

FIG. 8b is a schematic diagram showing electrical energy converting test results of a solar panel with a cooling device and a general solar panel according to the present invention.

### DETAILED DESCRIPTION OF THE PREFERRED EMBODIMENT

In order to further disclose the features and technical contents of the present invention, please refer to the following detailed descriptions of the invention and the accompanying drawings. The drawings are to be considered as illustrative drawings and should not be limited to these drawings.

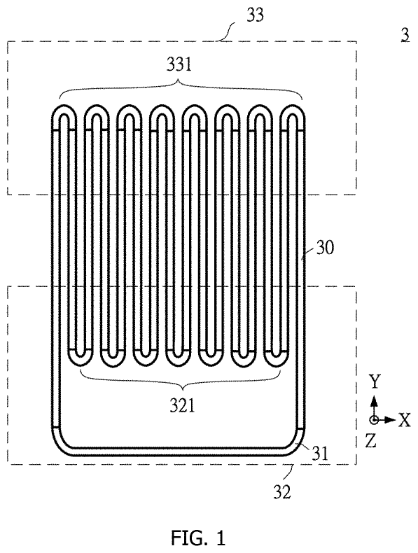

First, please refer to FIG. 1, which is a schematic diagram of the pulsed heat pipe of the present invention on the XY coordinate plane. As shown in FIG. 1, the present invention provides a Pulse Heat Pipe (PHP) 3, which is a metal tube that is bent into a heat transfer section 30 arranged at plural intervals. One end 33 (also referred to as condensing section) of the PHP is formed by an even number of bending section 331 of the heat transfer section 30 arranged at complex intervals (in other words, plural first bending section is formed by even numbers of bending section 331 of the heat transfer section 30 arranged at complex intervals and the corresponding other end 32 (also referred as the evaporation section), which is formed by an odd number of bending section 321 of the heat transfer section 30 arranged at complex intervals (in other words, plural second bending section is formed by an odd number of bending section 331 of the heat transfer section 30 arranged at complex intervals.) and the enclosed extended section 31 of the evaporation section, wherein the enclosed section 31 is used to surround to an odd numbers of bending section 321 of the heat transfer section 30 arranged at complex intervals. In a better embodiment of the present invention, enclosed section 31 surround a plurality of the heat transfer section 30 at intervals with odd number of heat transfer section 30 and the corresponding end of enclosed section 31 of the heat transfer section 30 at intervals with even number of the heat transfer section 30. In addition, the pulse heat pipe (PHP) 3 is a hollow metal pipe and its material and diameter can be adjusted according to the needs of the heat transfer. In a preferred embodiment of the present invention, the pulse heat pipe (PHP) 3 is a copper tube with an outer diameter of 3 mm and an inner diameter about 2 mm. By doing so, a light and thin design of the pulse heat pipe can be realized. Furthermore, in the embodiment of the present invention, inside the pulse heat pipe (PHP) 3 can be filled with a working liquid to act as a heat transfer medium and this liquid may be pure water.

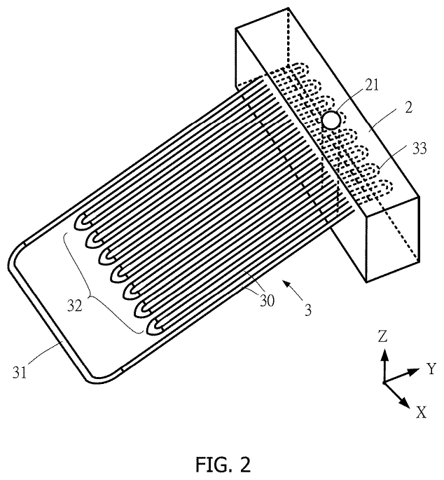

Next, please refer to FIG. 2, which is a perspective view of the pulsed heat pipe module of the present invention. As shown in FIG. 2, a section of the pulse heat pipe (PHP) 3 on the end 33 of the condensing section is connected to a regenerative tank 2, wherein the regenerative tank 2 is stored with a Phase Change Material (PCM) inside. The phase change material may be a solid-liquid phase change material, for example: the phase change material may be selected from paraffin, polyethylene glycol, calcium chloride, sodium sulfate, sodium carbonate, sodium hyposulfite, sodium phosphate, potassium phosphate, magnesium nitrate, magnesium chloride, barium hydroxide, or acetamide. Particularly, it should be emphasized that the phase change material of the present invention has the characteristic of absorbing heat source when it is in a solid state. When the phase change material is heated and reaches at its phase transition temperature, it will change from a solid state to a working liquid state after absorbing heat energy. After the phase change material cools down, it will return to a solid state.

Please continue referring to FIG. 2, the regenerative tank 2 has a chamber 20 and it has an pouring entrance 200 to let the phase change material be poured into the chamber 20 and a cap 21 for the pouring entrance 200 is provided so that the entrance can be sealed. In the embodiment of the present invention, firstly, the condensing section of the pulse heat pipe (PHP) 3 is connected to a regenerative tank 2. Its connecting method is to arrange the end 33 of the condensing section of the pulse heat pipe (PHP) 3 in the regenerative tank 2 and let the heat transfer section 30 arranged at plural intervals on the condensing section contact with the phase change material (PCM). Therefore, the absorbed heat can be transferred to the regenerative tank 2 by the liquid in the pulse heat pipe (PHP) 3 so that after absorbing the heat, the phase change material (PCM) in the regenerative tank 2 will be converted into a working liquid state from a solid state. Thus, the pulsed heat pipe module of the present invention has a function of dissipating heat. In addition, the present invention can also adjust the volume of the phase change material (PCM) in the regenerative tank 2 to absorb different heat amounts. For example, when using a large-capacity regenerative tank 2, the temperature of the solar panel can be reduced much more.

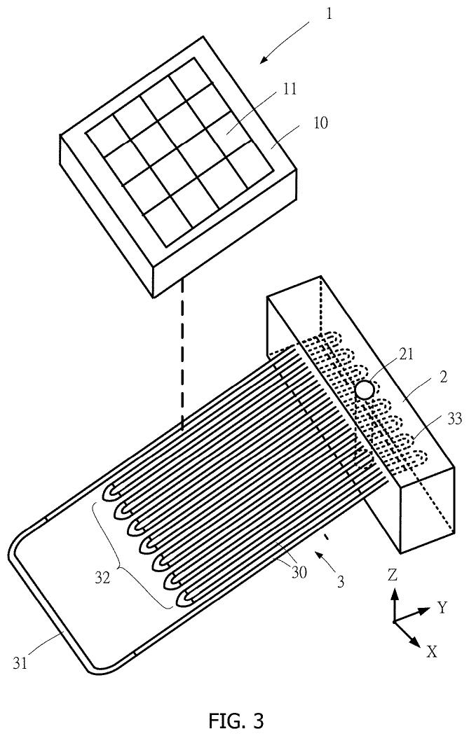

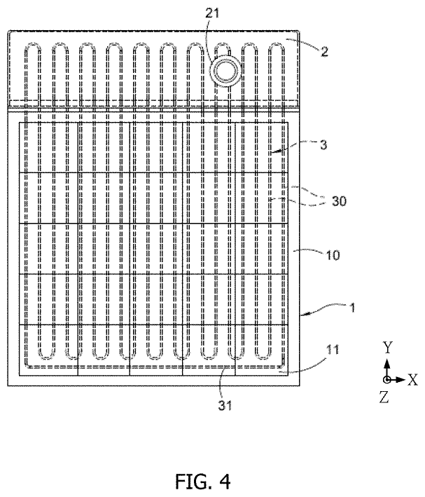

Next, please refer to FIG. 3 and FIG. 4, wherein FIG. 3 is a perspective view of a solar panel with a cooling device and FIG. 4 is a top perspective view of the solar panel with a cooling device on the BY coordinate plane. First, as shown in FIG. 3, the solar panel with a cooling device of the present invention includes: a solar panel 1, a regenerative tank 2, and at least one pulsed heat pipe 3, wherein: the solar panel 1 can include a substrate 10 and a plurality of solar cell 11 arranged on the substrate 10. In the embodiment of the present invention, the substrate 10 can be a rectangular frame and the solar cell 11 are arranged on a matrix inside the rectangular frame so that the solar cells 11 can be arranged in a larger area to face the sunlight and can be exposed to the sun directly in order to achieve the purpose of absorbing solar energy.

Next, in the present invention, which is a metal tube that is bent into a heat transfer section 30 arranged at plural intervals. One end 33 of the PHP is formed by an even number of bending section 331 of the heat transfer section 30 arranged at complex intervals and the corresponding other end 32 (also referred as the evaporation section), which is formed by an odd number of bending section 321 of the heat transfer section 30 arranged at complex intervals (in other words, plural second bending is formed by an odd number of bending section 331 of the heat transfer section 30 arranged at complex intervals.) and the enclosed extended section 31 of the evaporation section, wherein the enclosed section 31 is used to surround to an odd numbers of bending section 321 of the heat transfer section 30 arranged at complex intervals. An enclosed section 31 at the evaporation section of the pulse heat pipe 3 is connected to the substrate 10 of the solar panel 1. A section of the condensing end 32 is arranged in the regenerative tank 2 so that an even number of spaced-apart heat transfer section 30 are in contact with the phase change material. After the evaporation section of the pulse heat pipe 3 is connected to the substrate 10 of the solar panel 1, when the temperature of the solar panel 1 rises, the liquid is circulated in the heat transfer section 30 arranged at a plurality of intervals in the evaporation section of the pulse heat pipe 3. The circulation of the liquid transfers the heat to the phase change material in the regenerative tank 2 so that the heat from the high temperature of the liquid can be absorbed by the phase change material. Therefore, the temperature of the liquid flowing out of the heat storage tank 2 can be reduced. By circulating the liquid, the reduction of the temperature of the solar panel can be achieved so that the efficiency of converting solar energy to electrical energy can be upgraded. Also, In addition, in an embodiment of a standard pulse heat pipe module of the present invention, it is possible to simultaneously use a combination of several sets of pulse heat pipe modules 3 to cool the large-area solar panel 1. However, it is also possible to customize the pulse heat pipe module 3 with the regenerative tank 2 according to the area of the solar panel 1. As shown in FIG. 4, it is the upper perspective view of the solar panel with the temperature reduction device on the XY coordinate plane. This invention is not limited to the size and shape of the pulse heat pipe.

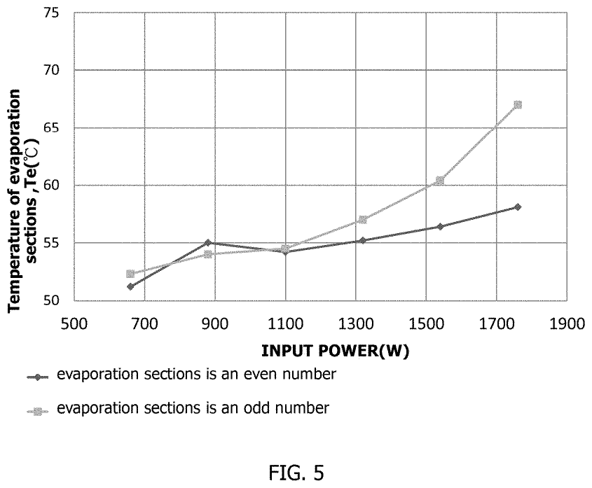

Next, please refer to FIG. 5, which is a schematic diagram of test results of a cooling device with the evaporation portion of the present invention. As shown in FIG. 5, it is shown that when both ends of the pulse heat pipe 3 shown in FIG. 1 (including one end of an even number of bending section 331 and one end of an odd number of bending section 321) are respectively arranged in the evaporation portion, the test results of the liquid under different evaporator temperatures at different powers. According to FIG. 5, the temperature reduction effect is not so oblivious and even no differences on the evaporation section of an odd and an even number of bending sections if it is under 1100 Watt or lower Watt, but if it is under higher Watt, such as over 1300 Watt, the temperature reduction effect on the evaporation section (condensing section is arranged on even number of bending section) of an odd number of bending section is better.

In other words, according to FIG. 5, it is preferable to arrange the odd bending section on the evaporation section while arranging the even number of bending section on the condensing portion.

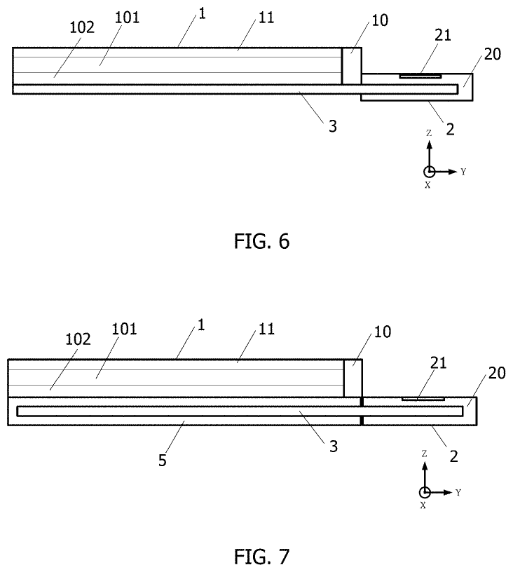

Next, please refer to FIG. 6, which is a cross-sectional view of a solar panel with a cooling device according to the present invention on the Z-Y coordinate plane. As shown in FIG. 6, the solar panel 1 has a package layer 100 to pack the outside of each solar cell 11 and a light transmissive layer 101 to cover on the solar cell 11. The package layer 100 mentioned above is usually made of a thermoplastic film, which is composed of ethylene-vinyl acetate (EVA). The back of the package layer 100 is supported by a support plate 102. In an embodiment of the present invention, the evaporation section of the pulse heat pipe 3 is corresponding to the support plate 102 of the solar panel 1 and the evaporation section of the pulse heat pipe 3 is in contact with the support plate 102. Then, when the solar panel 1 is placed at an angle perpendicular to the horizontal, for example, when the angle is between 15 and 25 degrees, a better electrical energy converting efficiency can be achieved. It is obvious that, as the embodiment mentioned above, when the embodiment is using the connecting structure described in FIG. 6 of the present invention, a better heat dissipation effect and a better electrical energy (power) converting efficiency can be realized.

In addition, the present invention can also directly connect the evaporation section of the pulse heat pipe 3 to the package layer 100 (EVA) of the solar panel 1 so that the heat on the solar panel 1 can be taken away more quickly. Better heat dissipation and better power (power) converting efficiency can be obtained.

Please refer to FIG. 7 again, which is a cross-sectional view of a solar panel with a cooling device according to the present invention on the Z-Y coordinate plane. As shown in FIG. 7, in order to achieve a better cooling effect, the present invention further arranged the evaporation section of the pulse heat pipe 3 into a water tank 5 under the structure of FIG. 5 so that the bending section 321 of an odd number of the heat transfer section 30 at intervals and the evaporation section formed by the outer enclosed extended section 31 are in contact with the fluid in the water tank 5, wherein the fluid may be water. At the same time, the condensing section formed by the bending part 331 of the even numbered of heat transfer section 30 at intervals is arranged in the regenerative tank 2. Then, when the water tank 5 is in contact with the support plate 102 of the solar panel 1 and the solar panel 1 is placed at an angle perpendicular to the horizontal, for example, when the angle is 15 degrees to 25 degrees, better electric (power) energy converting efficiency can be realized.

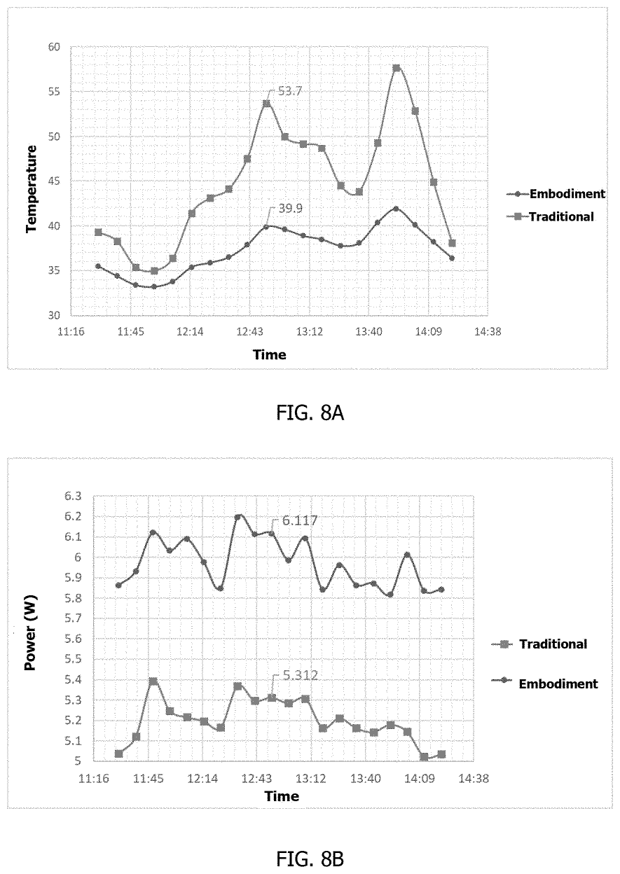

Finally, please refer to FIG. 8a and FIG. 8b, wherein FIG. 8a is a schematic diagram showing temperature test results of a solar panel with a cooling device and a general solar panel according to the present invention. FIG. 8b is a schematic diagram showing electrical energy converting test results of a solar panel with a cooling device and a general solar panel according to the present invention. A summary of the temperature test results according to FIG. 8a is shown in Table 1. We can see from Table 1 that the temperature of the solar panel equipped with the cooling device is lower than the temperature of the general solar panel at any time. Specifically, when the cooling device is comprised, the temperature of the solar panel can be reduced. The electrical energy converting test results of FIG. 8b are summarized and shown in Table 2. As we can see from Table 2, the electrical energy converting efficiency of the solar panel with the cooling device is higher than that of the general solar panel at any time. Specifically, when the cooling device is comprised, it can surely reduce the temperature of the solar panel and obtain better electric (power) energy converting efficiency.

In summary, the present invention can achieve the intended purpose and solve the previous problem of lacking the knowledge. Because of this innovation, it fully meets the requirements of the invention patent application. According to the patent law, please check and grant the patent for this case to protect the rights of the inventor.

What is claimed is:

1. A solar panel with a cooling device, comprising:
a solar panel with a substrate, a plurality of solar cells arranged on the substrate;
a regenerative tank is stored with a Phase Change Material (PCM) inside;
a pulsed heat pipe, bent into a plurality of heat transfer section arranged at intervals, comprising a plurality of first bending section on one end of the pulsed heat pipe, and an extended section on the corresponding other end of the pulsed heat pipe to surround a plurality of second bending section; and
a part of the extended section of the pulsed heat pipe is connected to the substrate of the solar panel, while the first bending section on the relative end of the extended section is extended into the regenerative tank and contacted with the phase change material.

2. The solar panel with the cooling device according to claim 1, wherein the pulsed heat pipe is filled with a working liquid.

3. The solar panel with the cooling device according to claim 2, wherein the working liquid is water.

4. The solar panel with the cooling device according to claim 1, wherein the heat transfer section extended into the regenerative tank and contacted with the phase change material comprise an even number of bending section.

5. The solar panel with the cooling device according to claim 1, wherein the solar panel further comprise a package layer to pack the outside of each of the solar cells, the part of the pulsed heat pipe corresponding to the solar panel is contacted with a back of the package layer.

6. The solar panel with the cooling device according to claim 1, wherein the phase change material is solid-liquid phase changed paraffin.

7. The solar panel with the cooling device according to claim 1, wherein the pulsed heat pipe is arranged at an angle with 15 degrees to 25 degrees intersecting to the plane of the horizon.

8. A solar panel with a cooling device, comprising:
a solar panel, comprising a substrate, a plurality of solar cells arranged on the substrate;
a regenerative tank is stored with a Phase Change Material (PCM) inside;
a water tank, configured to contain a fluid; and
a pulsed heat pipe, bent into a plurality of heat transfer section arranged at intervals, comprising a plurality of first bending section on one end of the pulsed heat pipe, and an extended section on the corresponding other end of the pulsed heat pipe to surround a plurality of second bending section; and
the extended section of the pulsed heat pipe is extended into the water tank and contacted with the fluid, the water tank is connected to the substrate of the solar panel, while the first bending section on the relative end of the extended section is extended into the regenerative tank and contacted with the phase change material.

9. The solar panel with the cooling device according to claim 8, wherein the pulsed heat pipe is filled with a working liquid.

10. The solar panel with the cooling device according to claim 9, wherein the working liquid is water.

11. The solar panel with the cooling device according to claim 8, wherein the heat transfer section extended into the regenerative tank and contacted with the phase change material comprise an even number of bending section.

12. The solar panel with the cooling device according to claim 8, wherein the solar panel further comprise a package layer to pack the outside of each of the solar cells, the part of the pulsed heat pipe corresponding to the solar panel is contacted with a back of the package layer.

13. The solar panel with the cooling device according to claim 8, wherein the phase change material is solid-liquid phase changed paraffin.
